(19) United States
(12) Patent Application Publication
(10) Pub. No.: US 2010/0308383 A1
(43) Pub. Date: Dec. 9, 2010

(54) SEMICONDUCTOR DEVICE HAVING A POROUS INSULATION LAYER WITH A PERMEATION PREVENTION LAYER COATING THE PORES AND METHOD FOR MANUFACTURING THE SAME

(76) Inventor: Min Jung SHIN, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/493,282

(22) Filed: Jun. 29, 2009

(30) Foreign Application Priority Data
Jun. 4, 2009 (KR) 10-2009-0049350

(51) Int. Cl. H01L 29/423; H01L 21/31; H01L 21/302

(52) U.S. Cl. 257/288; 438/778; 438/694; 257/632; 257/E29.132; 257/E21.24; 257/E21.214

(57) ABSTRACT

A semiconductor device having a porous insulation layer with a permeation prevention layer coating the pores for use in protecting against hydrogen permeation into source and drain areas is presented. The semiconductor device includes a conductive pattern, an insulation layer, and a permeation prevention layer. The conductive pattern is formed on a semiconductor substrate. The insulation layer is formed on a surface of the conductive pattern and includes a porous layer having a plurality of pores. The permeation prevention layer is formed on exposed surfaces of the pores in the porous layer.

### CROSS-REFERENCE TO RELATED APPLICATIONS

The present application claims priority to Korean patent application number 10-2009-0049350 filed on Jun. 4, 2009, which is incorporated herein by reference in its entirety.

### BACKGROUND OF THE INVENTION

The present invention relates to a semiconductor device and a method for manufacturing the same, and more particularly, to a semiconductor device which can realize a reduction in parasitic capacitance and can protect against hydrogen permeation and a method for manufacturing the same.

In general, a gate of a semiconductor device is composed of the stack layer of a gate insulation layer, a gate conductive layer and a gate hard mask layer that is formed on the gate conductive layer. Spacers, which comprise an oxide layer and a nitride layer, may be formed on both opposing sidewalls of the gate, and source and drain regions are formed in the surface of a semiconductor substrate on both opposing sides of the gate.

However, in the conventional art described above, after forming the gate, the spacers, and the source and drain regions, an interlayer dielectric is formed. Then, as the interlayer dielectric is CMPed (chemically mechanically polished) to expose the hard mask layer of the gate, and to expose the upper ends of the spacers. Specifically, if the oxide layer of the spacers is exposed, hydrogen is known to permeate through the oxide layer and believed to bond with dopant ions such as boron ions in the source and drain regions. As a result of hydrogen permeation the resultant performance characteristics of the gate are likely to become deteriorated.

The hydrogen permeation phenomenon through the oxide layer can be protected against, to some extent, by increasing the thickness of the nitride layer when forming the spacers. However, in this case, because the dielectric constant of the nitride layer is greater than that of the oxide layer, as the thickness of the nitride layer is increased the parasitic capacitance increases and as a result the operating speed of the semiconductor device decreases. Also, since the nitride layer comprises a material that is believed to apply a relatively high tensile stress to the gate, if a substantial amount of tensile stress is applied to the gate by the nitride layer, then the current of the gate is reduced. As a result, the characteristics and reliability of the semiconductor device are prone to becoming degraded. Therefore, a method capable of protecting against hydrogen permeation simultaneously causing an increase in parasitic capacitance is demanded in the art.

### BRIEF SUMMARY OF THE INVENTION

Embodiments of the present invention are directed to a semiconductor device that can protect against the permeation of hydrogen without increasing parasitic capacitance and a method for manufacturing the same.

Also, embodiments of the present invention are directed to a semiconductor device that can improve the characteristics and reliability of a semiconductor device and a method for manufacturing the same.

In one embodiment of the present invention, a semiconductor device comprises a conductive pattern formed on a semiconductor substrate; an insulation layer formed on a surface of the conductive pattern and including a layer that has a plurality of pores; and a permeation prevention layer formed on surfaces of the pores.

The conductive pattern comprises any one of a gate, a bit line, and a metal wire.

The insulation layer is formed on sidewalls of the conductive pattern.

The insulation layer comprises a nitride layer formed on sidewalls of the conductive pattern; and an oxide layer formed on the nitride layer and having a plurality of pores.

The permeation prevention layer comprises a nitride-based layer.

The nitride-based layer comprises at least one of a silicon nitride layer, a titanium nitride layer, an oxynitride layer, and a nitrided aluminum oxide layer.

In another embodiment of the present invention, a method for manufacturing a semiconductor device comprises the steps of forming a conductive pattern on a semiconductor substrate; forming an insulation layer which includes a layer having a plurality of pores, on a surface of the conductive pattern; and forming a permeation prevention layer on surfaces of the pores.

The conductive pattern comprises any one of a gate, a bit line, and a metal wire.

The step of forming the insulation layer comprises the steps of forming a nitride layer on the surface of the conductive pattern and the semiconductor substrate; forming an oxide layer on the nitride layer; and conducting a burn-out process for the oxide layer such that a plurality of pores are defined in the oxide layer.

The oxide layer is formed by using a SOD process or a sol-gel process.

The SOD process is conducted using HSQ (hydrogen silsesquioxane), NH₃ and H₂O, and the sol-gel process is conducted using tetra ethyl ortho silicate (TEOS).

The burn-out process is conducted at a temperature of about 300˜600° C. for about 10˜180 minutes.

The permeation prevention layer comprises a nitride-based layer.

The nitride-based layer comprises at least one of a silicon nitride layer, a titanium nitride layer, an oxynitride layer, and a nitrided aluminum oxide layer.

When the pores have a diameter of about 1˜99 nm, the permeation prevention layer on the surfaces of the pores is formed by using an ALD process.

The ALD process is conducted at a temperature of about 100˜300° C. under a pressure of about 50˜200 mTorr.

When the pores have a diameter of about 100˜500 nm, the permeation prevention layer on the surfaces of the pores is formed by using a CVD process.

The CVD process is conducted at a temperature of about 250˜500° C. under a pressure of about 10˜500 mTorr.

After the step of forming the permeation prevention layer, the method further comprises etching-back the resultant semiconductor substrate such that the insulation layer remains on sidewalls of the conductive pattern.

### BRIEF DESCRIPTION OF THE DRAWINGS

FIG. 1 is a sectional view illustrating a semiconductor device in accordance with an embodiment of the present invention.

FIGS. 2A through 2H are sectional views illustrating the processes of a method for manufacturing a semiconductor device in accordance with another embodiment of the present invention.

### DESCRIPTION OF SPECIFIC EMBODIMENTS

Hereafter, specific embodiments of the present invention will be described in detail with reference to the accompanying drawings. It is understood herein that the drawings are not necessarily to scale and in some instances proportions may have been exaggerated in order to more clearly depict certain features of the invention.

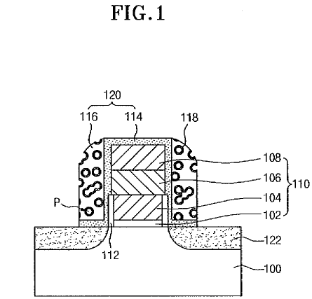

FIG. 1 is a sectional view illustrating a semiconductor device in accordance with an embodiment of the present invention. Referring to FIG. 1, a gate 110 having a multi-layered structure of a gate insulation layer 102, a polysilicon layer 104, a metal-based layer 106 and a gate hard mask layer 108 is formed on a semiconductor substrate 100. A first oxide layer 112 is selectively formed only on the sidewalls of the gate insulation layer 102 and the polysilicon layer 104.

A spacer insulation layer 120 is formed on the first oxide layer 112 and the sidewalls of the gate 110. The insulation layer 120 includes a first nitride layer 114 which is formed on the first oxide layer 112, the sidewalls of the gate 110 and portions of the semiconductor substrate 100 on both sides of the gate 110, and a second oxide layer 116 which is formed on the first nitride layer 114 and has a plurality of pores P.

The pores P communicate with one another in the second oxide layer 116. A permeation prevention layer 118 is formed on the surfaces of the pores P in the second oxide layer 116. The permeation prevention layer 118 comprises a nitride-based layer, for example, at least one of a silicon nitride layer, a titanium nitride layer, an oxynitride layer, and a nitrided aluminum oxide layer. Source and drain regions 122 are formed in the surface of the semiconductor substrate 100 on both sides of the gate 110.

In the semiconductor device according to the embodiment of the present invention, since the insulation layer 120 including the second oxide layer 116 having the plurality of pores P is formed on the sidewalls of the gate 110 and the permeation prevention layer 118 comprising a nitride-based layer is formed on the surfaces of the pores P, it is possible to protect against hydrogen from permeating through the second oxide layer 116. Therefore, in the present invention, it is possible to suppress hydrogen from bonding with boron ions in the source and drain regions 122 which is thought to deteriorate the performance characteristics of the gate 110.

Also, in the embodiment of the present invention, due to the fact that the permeation prevention layer 118 is formed on the surfaces of the pores P in the second oxide layer 116, it is not necessary to increase the thickness of the first nitride layer 114 constituting the spacer insulation layer 120 so as to protect against a hydrogen permeation phenomenon. Thus, in the present invention, because it is not necessary to increase the thickness of the first nitride layer 114 having a dielectric constant greater than an oxide layer, the hydrogen permeation phenomenon can be effectively avoided without experiencing an increase in parasitic capacitance caused due to an increase in the thickness of the first nitride layer 114. Therefore, it is possible to protect against the operating speed of a semiconductor device from decreasing due to the increase in the parasitic capacitance.

Further, in the embodiment of the present invention, because it is not necessary to increase the thickness of the first nitride layer 114 applying tensile stress to the gate 110, the tensile stress applied to the gate 110 by the first nitride layer 114 can be minimized. By doing this, in the present invention, it is possible to protect against the current of the gate 110 from being reduced, whereby the characteristics and reliability of the resultant semiconductor device can be improved.

Meanwhile, the present invention is not limitedly applied to the gate 110 and the insulation layer 120 formed on the sidewalls of the gate 110. Therefore, while not shown in a drawing, the present invention can be applied to conductive patterns of a semiconductor device and insulation layers formed on the surfaces of the conductive patterns, such as a bit line and an insulation layer formed on the surface of the bit line, and a metal line and an insulation layer formed on the surface of the metal line.

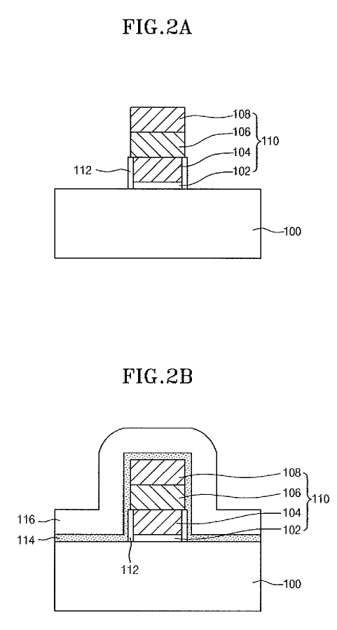

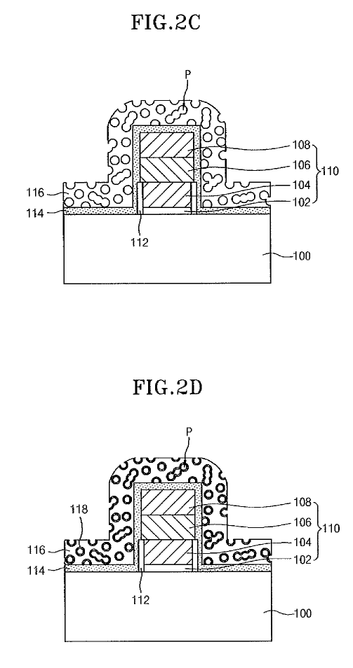

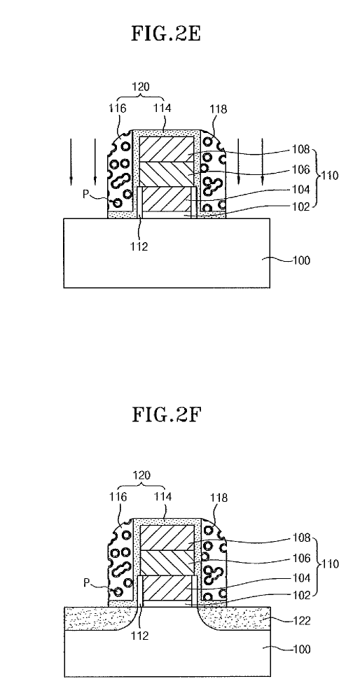

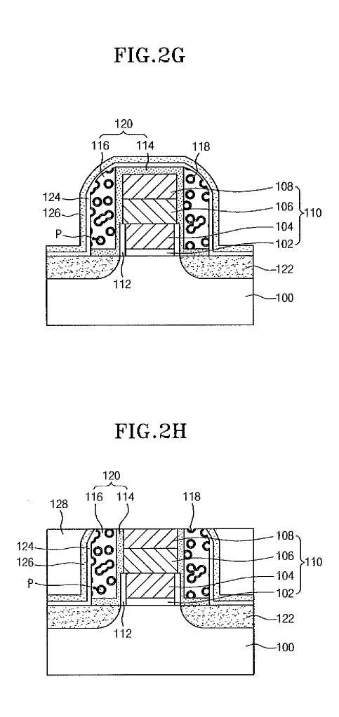

FIGS. 2A through 2H are sectional views illustrating the processes of a method for manufacturing a semiconductor device in accordance with another embodiment of the present invention.

Referring now to FIG. 2A, after forming a gate insulation layer 102, a polysilicon layer 104, a metal-based layer 106 and a gate hard mask layer 108 on a semiconductor substrate 100, by etching these layers 102, 104, 106 and 108, a gate 110, which comprises the multi-layered structure of the gate insulation layer 102, the polysilicon layer 104, the metal-based layer 106 and the gate hard mask layer 108, is formed. A first oxide layer 112 can be selectively formed only on the sidewalls of the gate insulation layer 102 and the polysilicon layer 104.

Referring to FIG. 2B, a first nitride layer 114 is formed on the first oxide layer 112, the sidewalls of the gate 110 and portions of the semiconductor substrate 100 on both sides of the gate 110. Then, a second oxide layer 116 is formed on the first nitride layer 114. The second oxide layer 116 is formed, preferably, to a thickness of about 300˜1,000 Å.

The second oxide layer 116 is formed, for example, by using an SOD (spin-on dielectric) process or a sol-gel process. The SOD process is conducted using hydrogen silsesquioxane (HSQ), NH₃ and H₂O, and includes a baking process that is conducted at a temperature of about 100˜200° C. under an atmospheric pressure. The sol-gel process is conducted using tetra ethyl ortho silicate (TEOS).

Referring to FIG. 2C, in order to define a plurality of pores P in the second oxide layer 116, a burn-out process is conducted for the second oxide layer 116. The burn-out process is conducted, for example, at a temperature of about 300˜600° C. for about 10˜180 minutes. At this time, the plurality of pores P are defined in the second oxide layer 116 in a manner such that they communicate with one another.

Referring to FIG. 2D, a permeation prevention layer 118 is formed on the surfaces of the pores P in the second oxide layer 116. The permeation prevention layer 118 comprises a nitride-based layer, for example, at least one of a silicon nitride layer, a titanium nitride layer, an oxynitride layer, and a nitrided aluminum oxide layer. The permeation prevention layer 118 is entirely formed on the surfaces of the second oxide layer 116 including the surfaces of the pores P and the surfaces of the first nitride layer 114.

The permeation prevention layer 118 is formed by using an ALD (atomic layer deposition) process or a CVD (chemical vapor deposition) process depending upon the average size of the pores P. In detail, when the pores P have an average diameter of several to several tens nanometers, for example, about 1˜99 nm, the permeation prevention layer 118 on the surfaces of the pores P is formed by using an atomic layering deposition (ALD) process. The ALD process is conducted at a temperature of about 100˜300° C. under a pressure of about 50˜200 mTorr. Also, when the pores P have an average diameter of several hundreds nanometers, for example, about 100˜500 nm, the permeation prevention layer 118 on the surfaces of the pores P is formed by using a chemical vapor deposition (CVD) process, for example, a PECVD (plasma-enhanced chemical vapor deposition) process. The PECVD process is conducted at a temperature of about 250˜500° C. under a pressure of about 10˜500 mTorr.

In the embodiment of the present invention, the average size of the pores P can be adjusted such that any one of the ALD process and the CVD process can be selected when forming the permeation prevention layer 118. For example, in the case of forming the second oxide layer 116 by using the sol-gel process, as the pH of a surfactant used in the sol-gel process is low, a pressure in the sol-gel process is low and a temperature in the sol-gel process is high, the size of the pores P can be increased. In the case of forming the second oxide layer 116 by using the SOD process, as a temperature in a post-processing process including a baking process is high, the average size of the pores P can be increased.

Referring to FIG. 2E, an etch-back process is conducted for the resultant semiconductor substrate 100 which is formed with the permeation prevention layer 118 such that the first nitride layer 114 and the second oxide layer 116 remain only on the sidewalls of the gate 110. As a result, a spacer insulation layer 120 including the first nitride layer 114 and the second oxide layer 116 is formed on the sidewalls of the gate 110. By conducting the etch-back process, portions of the permeation prevention layer 118 which are formed on the surfaces of the first nitride layer 114 and the second oxide layer 116 are removed, and the permeation prevention layer 118 remains substantially only on the surfaces of the pores P in the second oxide layer 116.

Referring to FIG. 2F, source and drain regions 122 are formed in portions of the semiconductor substrate 100 on both sides of the gate 110 on which the spacer insulation layer 120 is formed. The source and drain regions 122 are formed, for example, by using an ion implantation process using boron ions.

Referring to FIG. 2G, a third oxide layer 124 and a second nitride layer 126 are sequentially formed on the resultant semiconductor substrate 100 which is formed with the spacer insulation layer 120, the gate 110, and the source and drain regions 122. The third oxide layer 124 and the second nitride layer 126 function to protect the gate 110 while conducting a subsequent process, and are formed along the profile of the gate 110 including the spacer insulation layer 120.

Referring to FIG. 2H, an interlayer dielectric 128 is formed on the second nitride layer 126 in such a way as to fill the spaces between gates 110. Then, a chemical mechanical polishing (CMP) process is conducted to expose the upper surface of the gate 110, that is, the gate hard mask layer 108. While conducting the CMP process, portions of the interlayer dielectric 128, the second nitride layer 126, the third oxide layer 124 and the spacer insulation layer 120 are removed.

In the embodiment of the present invention, even though the second oxide layer 116 is exposed when the spacer insulation layer 120 is polished by using the CMP process, the pores P remain in and within the second oxide layer 116, and the permeation prevention layer 118 is formed on the surfaces of the pores P. Therefore, in the present invention, it is possible to protect against hydrogen from permeating through the exposed second oxide layer 116 during a subsequent process and the characteristics of the gate 110 from deteriorating thereby.

Thereafter, while not shown in a drawing, by sequentially conducting a series of well-known subsequent processes, the manufacture of a semiconductor device according to the embodiment of the present invention is completed.

As is apparent from the above description, in the present invention, since a spacer insulation layer including a second oxide layer having a plurality of pores is formed on sidewalls of a gate and a permeation prevention layer comprising a nitride-based layer is formed on the surfaces of the pores, it is possible to protect against hydrogen from permeating through the second oxide layer in a subsequent process. Therefore, in the present invention, it is possible to suppress permeated hydrogen from bonding with boron ions in source and drain regions to deteriorate the characteristics of the gate.

Also, in the present invention, due to the fact that the permeation prevention layer is formed on the surfaces of the pores in the second oxide layer to protect against the permeation of hydrogen, it is not necessary to form a thick first nitride layer constituting the spacer insulation layer in order to protect against a hydrogen permeation phenomenon. Thus, in the present invention, the hydrogen permeation phenomenon can be effectively avoided without experiencing an increase in parasitic capacitance caused due to an increase in the thickness of the first nitride layer having a dielectric constant greater than an oxide layer. Therefore, it is possible to protect against the operating speed of a semiconductor device from decreasing due to the increase in the parasitic capacitance.

Further, in the present invention, because it is not necessary to form a thick first nitride layer which is thought to impose a high tensile stress onto the gate, then the tensile stress applied to the gate by the first nitride layer can be minimized. Hence, in the present invention, it is possible to protect against the current of the gate from being reduced, and thereby improve the characteristics and reliability of the resultant semiconductor device.

Meanwhile, the present invention is not limitedly applied to the gate and the spacer insulation layer formed on the sidewalls of the gate. Therefore, while not shown in a drawing, the present invention can be applied to conductive patterns of a semiconductor device and insulation layers formed on the surfaces of the conductive patterns, such as a bit line and an insulation layer formed on the surface of the bit line, and a metal line and an insulation layer formed on the surface of the metal line.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device comprising:
a conductive pattern over a semiconductor substrate;
an insulation layer over a surface of the conductive pattern, wherein the insulation layer includes a porous layer that has a plurality of pores; and
a permeation prevention layer over surfaces of the pores.

2. The semiconductor device according to claim 1, wherein the conductive pattern comprises any one of a gate, a bit line, and a metal wire.

3. The semiconductor device according to claim 1, wherein the insulation layer is over sidewalls of the conductive pattern.

4. The semiconductor device according to claim 1, wherein the insulation layer comprises:
a nitride layer formed over sidewalls of the conductive pattern; and
an oxide layer formed over the nitride layer, wherein the oxide layer is the porous layer having the pores.

5. The semiconductor device according to claim 1, wherein the permeation prevention layer comprises a nitride-based layer.

6. The semiconductor device according to claim 5, wherein the nitride-based layer comprises at least one of a silicon nitride layer, a titanium nitride layer, an oxynitride layer, and a nitrided aluminum oxide layer.

7. A method for manufacturing a semiconductor device, the method comprising:
forming a conductive pattern over a semiconductor substrate;
forming an insulation layer over the conductive pattern, wherein the insulation layer includes a porous layer having a plurality of pores; and
forming a permeation prevention layer over surfaces of the pores.

8. The method according to claim 7, wherein the conductive pattern comprises any one of a gate, a bit line, and a metal wire.

9. The method according to claim 7, wherein the step of forming the insulation layer comprises:
forming a nitride layer over the conductive pattern and over the semiconductor substrate;
forming an oxide layer over the nitride layer; and
conducting a burn-out process to form the plurality of pores in the oxide layer, wherein the oxide layer is the porous layer.

10. The method according to claim 9, wherein the oxide layer is formed by using an spin-on dielectric (SOD) process or a sol-gel process.

11. The method according to claim 9, wherein the SOD process is conducted using HSQ (hydrogen silsesquioxane), NH₃ and H₂O, and the sol-gel process is conducted using tetra ethyl ortho silicate (TEOS).

12. The method according to claim 9, wherein the burn-out process is conducted at a temperature of about 300˜600° C. for about 10˜180 minutes.

13. The method according to claim 7, wherein the permeation prevention layer comprises a nitride-based layer.

14. The method according to claim 13, wherein the nitride-based layer comprises at least one of a silicon nitride layer, a titanium nitride layer, an oxynitride layer, and a nitrided aluminum oxide layer.

15. The method according to claim 7, wherein, when the pores have a diameter of about 1˜99 nm, the permeation prevention layer over the surfaces of the pores is formed by using an atomic layering deposition (ALD) process.

16. The method according to claim 15, wherein the ALD process is conducted at a temperature of about 100˜300° C. under a pressure of about 50˜200 mTorr.

17. The method according to claim 7, wherein, when the pores have a diameter of about 100˜500 nm, the permeation prevention layer over the surfaces of the pores is formed by using a chemical vapor deposition (CVD) process.

18. The method according to claim 17, wherein the CVD process is conducted at a temperature of about 250˜500° C. under a pressure of about 10˜500 mTorr.

19. The method according to claim 7, the method further comprises etching-back the resultant semiconductor substrate so that the insulation layer remains over sidewalls of the conductive pattern, wherein the etching-back step is performed after the step of forming the permeation prevention layer.
